(19) United States
(12) Patent Application Publication
(10) Pub. No.: US 2017/0229415 A1
(43) Pub. Date: Aug. 10, 2017

(54) METHOD OF MANUFACTURING SEMICONDUCTOR DEVICE HAVING BASE AND SEMICONDUCTOR ELEMENT AND SEMICONDUCTOR DEVICE

(71) Applicant: Kabushiki Kaisha Toshiba, Minato-ku (JP)

(72) Inventors: Yuchen HSU, Yokohama (JP); Daisuke HIRATSUKA, Yokohama (JP)

(73) Assignee: Kabushiki Kaisha Toshiba, Minato-ku (JP)

(21) Appl. No.: 15/427,466

(22) Filed: Feb. 8, 2017

(30) Foreign Application Priority Data
Feb. 9, 2016 (JP) 2016-022608

(51) Int. Cl. H01L 23/00

(52) U.S. Cl. CPC H01L 24/29; H01L 24/83; H01L 2224/8384; H01L 2224/29076; H01L 2224/29239; H01L 2224/29247; H01L 2224/29255; H01L 2224/29311; H01L 2224/29313; H01L 2224/29309; H01L 2224/29305

(57) ABSTRACT

In a method of manufacturing a semiconductor device of one embodiment, support members and a film which is formed of a paste containing metal particles and surrounds the support members are provided above a surface of a base. Then a semiconductor element is provided above the support members and the film. Subsequently, the film is sintered to join the base and the semiconductor element. The support members are formed of a metal which melts at a temperature equal to or below a sintering temperature of the metal particles contained in the paste. The support members support the semiconductor element after the semiconductor element is provided above the support members and the film.

### CROSS-REFERENCE TO RELATED APPLICATION

This application is based upon and claims the benefit of priority from the prior Japanese Patent Application No. 2016-22608, filed on Feb. 9, 2016, the entire contents of which are incorporated herein by reference.

### FIELD

Embodiments described herein relate generally to a method of manufacturing a semiconductor device having a base and a semiconductor element and to a semiconductor device.

### BACKGROUND

A technique which joins a semiconductor element to a base using a paste containing metal particles is known. In such a technique, assembly performance and reliability of a joining portion of a semiconductor device may lower, when the semiconductor element inclines with respect to a base and the thickness of the joining portion becomes uneven in a direction along a surface of the base. To suppress the lowering, a film which is formed of a paste containing metal particles and is provided between a semiconductor element and a base, and a plurality of support members are provided inside the film. A joining portion of high junction intensity is formed by sintering the paste containing the metal particles to make a junction organization dense. In the process, the distance between the semiconductor element and the base is maintained at a predetermined value by the support members, since the support members are not melted.

In this case, when the paste containing the metal particles is sintered to form the joining portion, the thickness of the joining portion decreases with progress of densifying the joining portion. Thus, in a case in which the distance between the semiconductor element and the base is maintained at the predetermined value by the support members, the reliability of the joining portion of the semiconductor device may lower because densification of the joining portion does not progress sufficiently. Further, a gap may be produced between the semiconductor element and the joining portion which are maintained at the predetermined distance by the support members. When the gap is produced between the semiconductor element and the joining portion, the reliability of the joining portion may lower.

### BRIEF DESCRIPTION OF THE FIGS

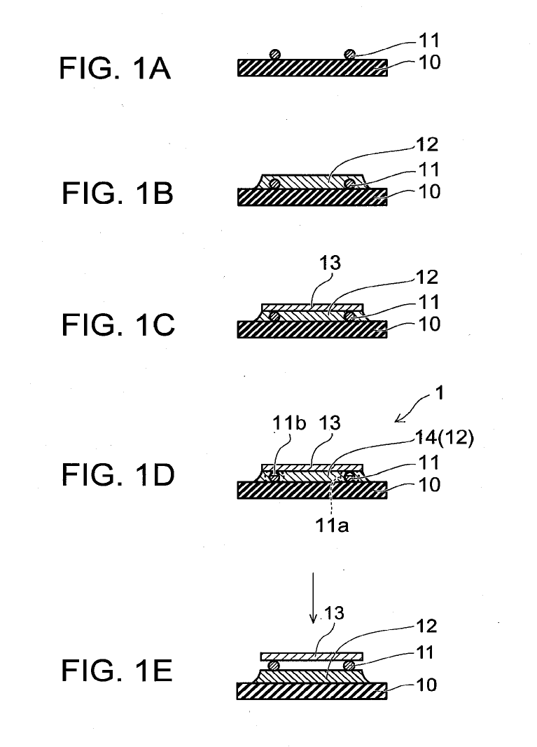

FIGS. 1A to 1D are sectional views schematically showing a plurality of steps in a method of manufacturing a semiconductor device according to a first embodiment, respectively.

FIG. 1E is a sectional view schematically showing a modification of a step of the method of manufacturing the semiconductor device according to the first embodiment.

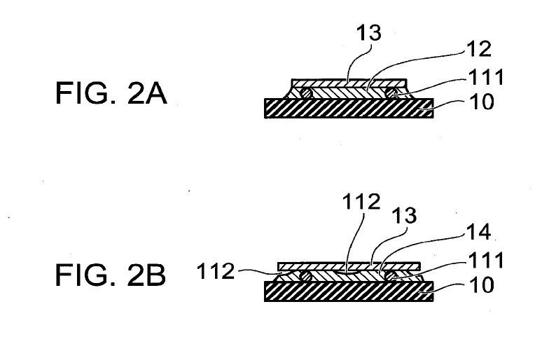

FIGS. 2A to 2B are sectional views schematically showing steps of forming a joining portion in a method of manufacturing a semiconductor device of a comparative example, respectively.

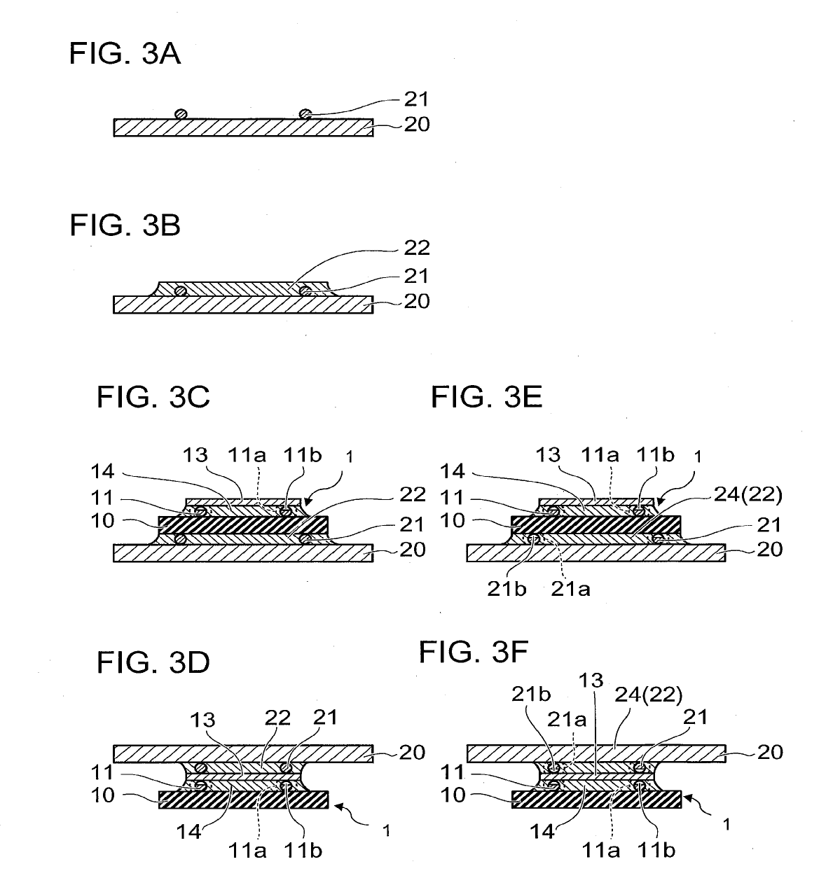

FIGS. 3A to 3F are sectional views schematically showing a plurality of steps in a method of manufacturing a semiconductor device according to a second embodiment, respectively.

### DETAILED DESCRIPTION

In a method of manufacturing a semiconductor device according to one embodiment, support members, and a film which is formed of a paste containing metal particles and surrounds the support members are provided above a surface of a base. Then a semiconductor element is provided above the support members and the film. Subsequently, the film is sintered to join the base and the semiconductor element. The support members are formed of a metal which melts at a temperature equal to or below a sintering temperature of the metal particles contained in the paste. The support members support the semiconductor element after the semiconductor element is provided above the support members and the film.

Hereinafter, further embodiments will be described with reference to the drawings. In the drawings, the same reference numerals denote the same or similar portions respectively.

FIGS. 1A to 1D are sectional views schematically showing a plurality of steps in a method of manufacturing a semiconductor device according to a first embodiment, respectively.

As shown in FIG. 1A, support members 11 are provided on one surface of a base 10 as a first base. The support members 11 are arranged in an area in which a film 12 of FIG. 1B described below and formed of a paste containing metal particles is to be provided. The base 10 may be a lead frame or a board. A thin plate body can be used as a lead frame. The lead frame may include an area in which a film 12 is provided and patterned portions provided in a circumference of the area. The lead frame can be formed of a metal such as an iron-nickel (Fe—Ni) alloy and a copper (Cu) alloy.

The board may be heat spreader or a wiring board. The heat spreader may be a plate body formed of a metal with high thermal conductivity such as a copper alloy and an aluminum (Al) alloy. The wiring board can be a plate-shaped base member formed of a thermally resistant material such as ceramics, silicon etc. and a wiring pattern can be arranged on one surface of the base member. The wiring pattern can be formed of a conductive material such as copper. A film which is formed of a material having high thermal conductivity such as copper can be provided on the other surface of the base member.

The support members 11 are formed of a metal as a second metal which melts at a temperature equal to or below a sintering temperature of the metal particles contained in the paste as described below. When the sintering temperature of the metal particles contained in the paste is taken into consideration, it is desirable to form the support members 11 by using an alloy containing tin (Sn) as a main constituent i.e. a tin alloy, for example. The support members 11 can be made of a material containing tin as a main constituent and additionally at least one selected from the group of bismuth (Bi), indium (In) and gallium (Ga). When these elements are added to tin, the melting point can become within the range from 130° C. or higher to 230° C. or below.

The shape of the support members 11 is not particularly limited but may have a spherical shape, a column shape, a line shaped or a block shape. The shape of the support members 11 illustrated in FIG. 1A is spherical. The number of the support members 11 is not particularly limited, but the position of a semiconductor element 13 of FIG. 1C described below to be supported by the support member 11 can be sufficiently stabilized when the number of support members 11 is three or more.

As described below referring to FIG. 1D, when the support members 11 are melted, voids 11b may arise in the support members 11. When the voids 11b arise in the support members 11, the thermal resistance may become large. If the number of the support members 11 is made too large or the size of the support members 11 is made too large in order to suppress increase of the thermal resistance, heat dissipation may not be performed from the semiconductor element 13 sufficiently. According to the inventors' simulation, it was found that fall of heat dissipation can be suppressed sufficiently by setting A1 and A2 to satisfy A1/A2≦0.02, when A1 is an area which the support members 11 occupy and A2 is an area which the film 12 occupies respectively on the base 10.

The position of the support member 11 in a planar direction is not particularly limited, but the position of the semiconductor element 13 can be stabilized and in addition the uniformity of the thickness of a joining portion 14 of FIG. 1D described below can be attained, when the support members 11 are arranged with a substantially equal distance provided between each one of the support members 11 and another one of the support members 11 close to each one of the support members 11, in the area in which the film 12 is arranged.

As shown in FIG. 1B, a film 12 formed of a paste containing metal particles is provided to cover the support members 11, after the support members 11 are provided on the base 10. In this case, the distance between an upper surface of the film 12 and the one surface of the base 10 is made larger than the distances between upper ends of the support members 11 and the one surface of the base 10. The support members 11 are provided adjacently to the film 12 to surround the film 12. In other words, the support members 11 are arranged such that the support members 11 are buried in an interior of the film 12.

The film 12 can be formed by a screen-printing method, an ink-jet method, etc. The paste can contain metal particles, an organic solvent having volatility, and a dispersing agent. In this case, the paste can be formed by kneading metal particles, an organic solvent and a dispersing agent. The viscosity of the paste is adjusted so that the shape of the film 12 can be maintained. The viscosity of the paste can be adjusted by selecting the quantity of the organic solvent.

The material of the metal particles which is a first metal may be silver (Ag), copper (Cu) or nickel (Ni). The diameters of the metal particles may be 1 nm or more and 10000 nm or less. In this case, the paste may include metal particles which have different diameters or which have substantially the same diameter.

The sintering temperature can be low if the diameters of the metal particles are made small. However, it is difficult to manufacture metal particles of small diameters. Thus, the paste may include metal particles of small diameters and large diameters. In this way, lowering of the sintering temperature and increase of the productivity of the metal particles can be attained. The mixture rate of the metal particles of small diameters may be suitably determined according to the kind of the material, the sintering temperature to be permitted etc. of the metal particles.

The organic solvent may be a hydrocarbon based solvent, a higher alcohol or toluene. The dispersing agent may be a fatty acid containing polyvalent carboxylic acid, an anionic based dispersing agent containing unsaturated fatty acid, a polymer based ionic dispersing agent or a phosphoric acid ester based compound.

The embodiment illustrates the case in which the support members 11 are provided on the one surface of the base 10 and the film 12 is provided to cover the support members 11, but the invention is not limited to the case. For example, as shown in FIG. 1E, a film 12 may be provided on the one surface of the base 10, then support members 11 may be provided on the film 12, and subsequently a semiconductor element 13 may be impressed onto an upper surface of the film 12 to move the support members 11 into an interior of the film 12. According to this method, a state as shown in FIG. 1C can be obtained.

As another method, a paste containing metal particles to which support members 11 are added may be applied onto the one surface of base 10 to obtain a state as shown in FIG. 1B. By this method, the support members 11, and a film 12 which is formed of the paste containing of the metal particles and surrounds the support members 11 can be provided simultaneously above the one surface of the base 10. In order to provide support members 11 at preferable positions easily, it is desirable to provide the support members 11 on one surface of a base 10 and then to provide a film 12 to cover the support member 11, as done in the embodiment.

In the embodiment, as shown in FIG. 1C, a semiconductor element 13 is provided on the film 12 after the steps of FIGS. 1A and 1B. Further, the distance between the semiconductor element 13 and the base 10 is made small. In order to make the distance small, for example, the semiconductor element 13 maybe pressed toward the base 10, the base 10 may be pressed toward the semiconductor element 13, or both the semiconductor element 13 and the base 10 may be pressed so that the semiconductor element 13 and the base 10 can approach to each other. By such pressing, a lower surface of the semiconductor element 13 comes into close contact with an upper surface of the film 12. Further, the lower surface of the semiconductor element 13 comes into close contact with upper ends of the support members 11. Accordingly, the distance between the semiconductor element 13 and the base 10 is maintained at a predetermined value by the support members 11 and the support members 11 support the semiconductor element 13.

The semiconductor element 13 may be a power semiconductor element or a semiconductor light emitting element. The power semiconductor device may be an insulating gate bipolar transistor (IGBT) or an insulating gate field effect transistor (MOSFET). The semiconductor light emitting element is a light emitting diode (LED) for example.

Then, as shown in FIG. 1D, the film 12 is sintered and the base 10 and the semiconductor element 13 are joined to make a semiconductor device 1. By sintering the film 12, a joining portion 14 is formed. Further, when the film 12 is sintered, the support members 11 melt. The joining portion 14 becomes a sintered body having a porous structure. Thus, parts of the support members 11 which are melted when the film 12 is sintered may go into holes of the porous structure so that penetrated portions 11a may be formed. When the parts of the support members 11 go into the holes of the porous structure, the volumes of the support members 11 decrease by the penetrated amount so that voids 11b may be formed.

The sintering temperature can be suitably determined based on the kind of material and the diameters of the metal particles contained in the paste 12. The sintering temperature can be determined according to a result of performing an experiment or a simulation. The sintering temperature of the metal particles may exceed 230° C. For example, when the material of the metal particles is silver and the mean diameter of the metal particles is about 100 nm, the sintering temperature of the metal particles can be about 250° C. When the material of the metal particles is copper and the mean diameter of the metal particles is about 90 nm to about 2.0 μm, the sintering temperature of the metal particles can be about 250° C. to about 350° C. When the material of the metal particles is nickel and the mean diameter of the metal particles is about 90 nm to about 10 μm, the sintering temperature of the metal particles can be about 350° C.

When the material of the support members 11 is a tin alloy, the melting point of the support members 11 can be 250° C. or less. For example, when at least one selected from the group of bismuth, indium and gallium is added to tin, the melting point of the support members 11 can be within the range of 130° C. or above and 230° C. or below. It is possible to control the melting point of the support members 11 so that the melting point may become a desirable value, by adjusting the amounts of these elements to be added.

The sintering of the film 12 can be performed in the air, a decompressed atmosphere or a gas atmosphere. The sintering of the film 12 can be performed using a hot plate, a heating furnace, etc. According to the plurality of steps described above, the semiconductor element 13 and the base 10 can be joined to each other.

Formation of the joining portion 14 by a method of manufacturing a semiconductor device of a comparative example will be described below. FIGS. 2A to 2B are sectional views schematically showing steps of forming the joining portion 14 in the method of manufacturing the semiconductor device of the comparative example, respectively. As shown in FIG. 2A, a film 12 formed of a paste containing metal particles is provided to cover support members 111. Further, a semiconductor element 13 is provided on the film 12. Then, a semiconductor element 13 is pressed toward the base 10. As a result, a lower surface of the semiconductor element 13 comes into close contact with an upper surface of the film 12. The lower surface of the semiconductor element 13 comes into close contact with upper surfaces of the support members 111. Accordingly, the distance between the semiconductor element 13 and the base 10 is maintained at a predetermined value by the support members 111.

Then, the paste is sintered to form a joining portion 14. In the method of manufacturing the semiconductor device of the comparative example, the support members 111 are formed of a material such as copper and nickel which can melt at a temperature exceeding the sintering temperature of the metal particles contained in the paste. Thus, when the paste is sintered to form the joining portion 14, the support members 111 do not melt.

In the comparative example, when the paste containing the metal particles is sintered, necks i.e. a bonding portion are formed among the metal particles. As the necks grow, holes among the metal particles decrease and the distance between the metal particles becomes small. Accordingly, the volume of the joining portion 14 becomes smaller than the volume of the film 12. As a result, the thickness of the joining portion 14 becomes smaller than the thickness of the film 12. In this case, the distance between the semiconductor element 13 and the base 10 is maintained at a predetermined value because the support members 111 do not melt.

Thus, as shown in FIG. 2B, a hollow 112 may be formed between the semiconductor element 13 and the joining portion 14. When the hollow 112 is formed between the semiconductor element 13 and the joining portion 14, the junction intensity between the semiconductor element 13 and the joining portion 14 lowers, or stress concentration arises. Thus, the reliability of the joining portion 14 may lower.

On the other hand, according to the embodiment, the support members 11 are formed of the material which melts at the temperature below the sintering temperature of the metal particles contained in the paste. When the paste is sintered to form the joining portion 14 and at the time the support members 11 are caused to melt, a close contact state between the lower surface of the semiconductor element 13 and the upper surface of the film 12 can be maintained, even if the thickness of the joining portion 14 decreases. The thickness of the film 12 decreases in the step in which the film 12 is sintered to join the base 10 and the semiconductor element 13. At this time, the position of the pressed semiconductor element 13 changes so as to make the semiconductor element 13 descend following reduction of the thickness of the film 12 by melting of the support members 11.

Thus, since a hollow is suppressed to arise between the semiconductor element 13 and the joining portion 14, the reliability of the joining portion 14 can be raised. The amount of reduction of the thickness of the film 12 with sintering is small. Inclination of the semiconductor device 12 occurs mainly in a process of providing the semiconductor element 13 on the film 12 and shortening the distance between the semiconductor element 13 and the base 10. In the embodiment, inclination of the semiconductor element 13 before sintering is suppressed by the support members 11. Thus, the semiconductor element 13 does not incline greatly even if the position of the semiconductor element 13 is changed following reduction of the thickness of the film 12.

After the step of FIG. 1D, an electrode of the semiconductor element 13 and the base 10 are electrically connected, if needed. For example, the electrode of the semiconductor element 13 and the base 10 are electrically connected by wiring using a wire bonding method. Further, the semiconductor element 13 and a wiring provided by the wire bonding method are sealed with resin.

Any of the wiring and the sealing with resin is not always necessary. For example, when a flip chip bonding for the semiconductor element 13 is carried out, connecting by wiring is not necessary. The sealing with resin can be omitted in a case that the semiconductor element 13 is contained in a package which is composed of a metal, ceramics, etc. The embodiment shows a case where the semiconductor device 1 having the base 10, the support members 11, the semiconductor element 13 and the joining portion 14 is manufactured. Specifically, the joining portion 14 is a sintered body of a metal such as silver, copper and nickel and is provided between the base 10 and the semiconductor element 13. The support members 11 are provided between the base 10 and the semiconductor element 13 and contain a metal such as the above-described tin alloy which has a melting point of the sintering temperature of the metal or below. The joining portion 14 is configured to surround the support members 11. As explained below, further another element may be joined to such a semiconductor device 1.

FIGS. 3A to 3F are sectional views schematically showing a plurality of steps in a method of manufacturing a semiconductor device according to a second embodiment, respectively. The second embodiment is a method of manufacturing a semiconductor device in which further another step is added to the first embodiment. As shown in FIG. 3A, support members 21 are provided on one surface of a base 20 as a second base. The support members 21 are provided in an area in which a film 22 of FIG. 3B described below and formed of a paste containing metal particles is to be provided. The base 20 may be a heat-radiating member such as a heat spreader, a heat-radiating plate or a heat sink. The heat-radiating member may be formed of a metal with high thermal conductivity such as a copper alloy and an aluminum alloy.

The support member 21 is formed of a material which can melts at a temperature equal to or below a sintering temperature of the metal particles contained in the paste. The material of the support members 21 may be the same as that of the support members 11 used in the first embodiment. When the material of the support members 21 is a tin alloy, the melting point of the support members 21 can differ from that of the support member 11 of the first embodiment by adjusting the quantity of an element to be added such as bismuth, indium and gallium. In this case, when the melting point of the support members 21 is lower than that of the support member 11, melting of the support member 11 is suppressed in sintering the film 22. The suppression of melting suppresses growth of voids 11b as shown in FIG. 1D. The shape, number and occupation area of the support members 21 may be the same as those of the support member 11 or different from those of the support member 11.

Then, as shown in FIG. 3B, a film 22 formed of a paste containing metal particles is provided to cover and surround the support members 21. In this case, the distance between an upper surface of the film 22 and the one surface of the base 20 is made larger than the distance between upper ends of the support members 21 and the one surface of the base 20.

The film 22 may be formed by a screen-printing method, an ink-jet method, etc. An organic solvent and a dispersing agent which are contained in the paste for forming the film 22 may be the same as those contained in the paste used to form the film 12 of the first embodiment, or different from those contained in the paste used to form the film 12.

The material and diameter of the metal particles which are contained in the paste used to form the film 22 may be the same as those of the metal particles contained in the paste used to form the film 12, or different from those of the metal particles contained in the paste used to form the film 12. In this case, the sintering temperature of the film 22 can differ from that of the film 12 by changing at least one of the material and the diameter of the metal particles. For example, the sintering temperature of the film 22 can become lower than that of the film 12 by making the diameter of the metal particles contained in the film 22 smaller than that of the metal particles contained in the film 12. By such a setting, the support members 11 are suppressed to melt when the film 22 is sintered.

The above explanation shows a case where the support members 21 are provided on the one surface of the base 20 and the film 22 is provided to cover the support members 21, but the invention is not always limited to the case. For example, after a film 22 is provided on one surface of the base 20, support members 21 may be provided on the film 22. In this case, in a subsequent step described below, when the base 10 or the semiconductor element 13 is impressed onto an upper surface of the film 22, the support members 21 are moved to an interior of the film 22.

A paste in which support members 21 are further added may be applied to one surface of a base 20. Specifically, support members 21 may be mixed to a paste containing metal particles, and then the paste may be applied to one surface of a base 20 to form a film 22 of the paste which covers the one surface of the base 20. But, it is easier to provide the support members 21 at a desired position when the support members 21 are provided on the one surface of the base 20 and then the film 22 of the paste is provided to cover the support member 21.

Subsequently, as shown in FIG. 3C, the semiconductor device 1 made by the steps of FIGS. 1A to 1D is provided on the film 22 with the base 10 of the semiconductor device 1 facing downward. Further, the semiconductor device 1 is pressed toward the base 20. As a result, a lower surface of the base 10 comes into close contact with an upper surface of the film 22, and the lower surface of the base 10 comes into close contact with upper ends of the support members 21. Accordingly, the distance between the semiconductor device 1 and the base 20 is maintained at a predetermined value by the support members 21, and the support members 21 support the semiconductor device 1. As shown in FIG. 3D, by reversing the up-and-down of the semiconductor device 1, the semiconductor device 1 may be provided on the film 22 with the semiconductor element 13 of the semiconductor device 1 facing upward.

Two bases on which a film of a paste containing support members and metal particles may be provided respectively on a side of the base 10 of the semiconductor device 1 and on a side of the semiconductor element 13 of the semiconductor device 1.

Then, the film 22 is sintered to join the base 20 and the semiconductor device 1, as shown in FIG. 3E indicating the case where the step of FIG. 3C is adopted, or as shown in FIG. 3F indicating the case where the step of FIG. 3D is adopted. By sintering the film 22, a joining portion 24 is formed. When the film 22 is sintered, the support members 21 melt. The sintering of the film 22 can be performed similarly to the sintering of the film 12 of the first embodiment.

Since the joining portion 24 becomes a sintered body, the joining portion 24 becomes a porous structure. Thus, parts of the melted support members 21 go into holes of the porous structure and penetrated portions 21a may be formed, when the film 22 is sintered. In addition, when the parts of the support members 21 go into the holes of the porous structure, the volume of the support member 21 decreases by the penetration amount so that voids 21b may be formed in the support members 21. In this way, the semiconductor device 1 can be joined to the base 20.

The support members 21 are formed of the material which can melt at the temperature equal to or below the sintering temperature of the metal particles contained in the paste. The state that the lower surface of the base 10 or the upper surface of the semiconductor element 13 is in close contact with the upper surface or the lower surface of the film 22 can be maintained by making the support members 21 melt, when the paste is sintered to form the joining portion 24, even if the thickness of the joining portion 24 decreases. Specifically, in the step of sintering the film 22 to join the base 20 and the semiconductor device 1, the thickness of the film 22 decreases. At this time, the position of the semiconductor device 1 changes following reduction of the thickness of the film 22 by melting of the support members 21.

Since production of a hollow between the semiconductor device 1 and the joining portion 24 can be suppressed, the reliability of the joining portion 24 can be raised. The amount of change of the thickness of the film 22 with sintering is small. Thus, inclination of the semiconductor device 1 arises mainly in the step of providing the semiconductor device 1 on the film 22 and of shortening the distance between the semiconductor device 1 and the base 20. In the method of manufacturing the semiconductor device according to the second embodiment, inclination of the semiconductor device 1 is suppressed by the support members 21 before sintering the semiconductor device 1. Accordingly, the semiconductor device 1 does not incline greatly even if the position of the semiconductor device 1 is changed following reduction of the thickness of the film 22.

The semiconductor device shown in FIG. 3E or 3F has the structure of having the base 20, the support members 21 and the joining portion 24 in addition to the semiconductor device 1. The base 20 may be joined to the side of the base 10 of the semiconductor device 1 or the side of the semiconductor element 13 of the semiconductor device 1. Specifically, the joining portion 24 is provided between the base 20 and the semiconductor element 13 or the base 10, and is a sintered body of the metal mentioned above. The support members 21 are provided between the base 20 and the semiconductor element 13 or the base 10, and contain the metal which has the melting point equal to or below the sintering temperature of the metal contained in the film 22. The joining portion 24 is configured to surround the support members 21. When the melting point of the support member 21 made lower than the melting point of the support member 11, the support members 11 are suppressed to melt in forming the joining portion 24 by sintering. The number of the support members 21 may be three or more.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
providing support members, and a film which is formed of a paste containing metal particles and surrounds the support members, above a surface of a base;
providing a semiconductor element above the support members and the film; and
sintering the film to join the base and the semiconductor element, wherein
the support members are formed of a metal which melts at a temperature equal to or below a sintering temperature of the metal particles contained in the paste and support the semiconductor element after the semiconductor element is provided above the support members and the film.

2. The method according to claim 1, wherein the metal particles include at least one of silver, copper or nickel, and the diameters of the metal particles are 1 nm or more and 10000 nm or less.

3. The method according to claim 1, wherein the support members contain tin as a primary constituent and in addition at least one selected from a group of bismuth, indium and gallium.

4. The method according to claim 2, wherein the support members contain tin as a primary constituent and in addition at least one selected from a group of bismuth, indium and gallium.

5. The method according to claim 2, wherein, in sintering the film to join the base and the semiconductor device, the thickness of the film decreases and the support members melt so that the position of the semiconductor device changes following reduction of the thickness.

6. The method according to claim 2, wherein, in sintering the film to join the base and the semiconductor device, the thickness of the film decreases and the support members melt so that the position of the semiconductor device changes following reduction of the thickness.

7. The method according to claim 3, wherein, in sintering the film to join the base and the semiconductor device, the thickness of the film decreases and the support members melt so that the position of the semiconductor device changes following reduction of the thickness.

8. The method according to claim 4, wherein, in sintering the film to join the base and the semiconductor device, the thickness of the film decreases and the support members melt so that the position of the semiconductor device changes following reduction of the thickness.

9. The method according to claim 1, wherein providing the support members and the film above the surface of the base is carried out by providing the support members on the surface of the base and forming the film so that the support members may be covered with the film.

10. The method according to claim 1, wherein the step of providing the support members and the film above the surface of the base and of providing the semiconductor device above the film is carried out by forming the film on the surface of the base, providing the support members on the film, providing the semiconductor device on the support members and pressing the semiconductor device to move the support members in a direction to the base.

11. The method according to claim 1, wherein the paste further contains an organic solvent and a dispersing agent.

12. A semiconductor device, comprising:
a base;
a semiconductor element provided above the base;
support members provided between the base and the semiconductor element;
a joining portion which is provided between the base and the semiconductor element to join the base and the semiconductor element and surrounds the support members, wherein
the joining portion contains a first metal and the support members contains a second metal, and the melting point of the second metal is equal to or below the sintering temperature of the first metal.

13. The device according to claim 12, wherein the joining portion has a porous structure and part of the support members are provided in holes of the porous structure.

14. The device according to claim 12, wherein the support members include a void.

15. The device according to claim 13, wherein the support members include a void.

16. The method according to claim 1, wherein the metal particles include at least one of silver, copper or nickel, and the diameters of the metal particles are 1 nm or more and 10000 nm or less.

17. The method according to claim 12, wherein the support members contain tin as a primary constituent and in addition at least one selected from a group of bismuth, indium and gallium.

18. The method according to claim 16, wherein the support members contain tin as a primary constituent and in addition at least one selected from a group of bismuth, indium and gallium.
